(19) United States
(12) Patent Application Publication
(10) Pub. No.: US 2006/0244461 A1
(43) Pub. Date: Nov. 2, 2006

(54) Intelligent portable personal communication device

(76) Inventors: Yuh-shen Song, Northridge, CA (US); Catherine Lew, Northridge, CA (US); Alexander Song, Northridge, CA (US); Victoria Song, Northridge, CA (US)

Correspondence Address: FULBRIGHT AND JAWORSKI LLP, 555 S. FLOWER STREET, 41ST FLOOR, LOS ANGELES, CA, 90071, US

(21) Appl. No.: 11/335,915

(22) Filed: Jan. 18, 2006

Related U.S. Application Data
(60) Provisional application No. 60/644,752, filed on Jan. 19, 2005.

(51) Int. Cl. G01R 31/00

(52) U.S. Cl. 324/500; 427/127; 600/532

(57) ABSTRACT

An intelligent portable personal communication device, such as a cellular phone, integrates and interfaces an array of sensors and monitors to detect adverse situations and make phone calls to predefined third parties so that they can take appropriate actions for the benefits of the user. The intelligent portable personal communication device can determine the position of the device with sufficient precision so that the third parties can locate the user based on the position information and/or by means of a special location beacon signal transmitted by the device. Furthermore, the intelligent portable personal communication device can block the user from any conversation with certain predefined parties, or inform the phone company to begin recording the phone conversation, when the user's breath alcohol level reaches a predefined value. A networked computer can use the position information to coordinate the activities among multiple parties through their respective portable personal communication devices.

This application claims priority of U.S. provisional patent application No. 60/644,752 filed on Jan. 19, 2005, which is hereby incorporated by reference in its entirety.

### FIELD OF INVENTION

The present invention relates generally to the provision of intelligent personalized services from a user's cell phone or other portable personal communication devices. More specifically, the present invention uses one or more sensors or wirelessly connected portable devices to detect abnormal and potentially dangerous conditions that could have an adverse effect on the user. In response to the detection of such events, the present invention determines the position of the device and attempts to initiate or block a communication, based on a set of predefined rules, with a predetermined party in order to mitigate any consequent harm to the user.

### BACKGROUND OF THE INVENTION

Many patients with an adverse health condition may need emergency care from time to time. Such a patient may lose consciousness when alone at home and cannot call “911” or other help services. In that event, the patient may simply die quietly at home because no help was available during an emergency.

Even for a person in normal health, he/she may not be conscious to make a decision to handle an adverse condition. For example, a person may be caught in a fire while asleep. A healthy person may also become unconscious as a result of a gas leakage or a terrorist attack involving a toxic gas.

It is also possible that a person is not subject to a true emergency condition but may nevertheless still be vulnerable. For example, a drunken person may no longer be sufficiently alert to call a relative or friend to pick him/her up from a bar, but rather may eventually fall asleep on the street and be exposed to a great deal of risks.

In the winter of year 2004, a young couple was frozen to death near Omaha, Nebr., USA. Even though they had called “911” for help through their cellular phones, policemen could not identify their exact location. The only information could be given to the “911” team by the young couple is that they were somewhere near Omaha. When the rescue team eventually found them, it was too late.

The discovery in 1953 that absorption of a gas onto the surface of a metal oxide semiconductor produced a large change in its electrical resistance signaled the advent of semiconductor sensor technology.

In 1962, the first chemo-resistive semiconductor gas sensor was invented for gas detection. Since then, semiconductor gas sensors have been widely used a as domestic and industrial gas detectors for gas-leak alarm, fire alarm, process control, pollution control, etc.

The FY 2003 President's budget requested $710 million for the U.S. federal investment in nanoscale science, engineering, and technology, and a majority of the funds were used for applying nanotechnology for chemical-biological-radioactive detection through sensors. Sensors can detect a variety of conditions today.

Personal communication device such as cellular phones, personal digital assistants (PDAs), palm computers, etc. have become an integral part of our daily life today. According to the statistics published by the telecommunication industry in December 2004, there are more than 130 million cellular phone subscribers in the USA. Most people are carrying cellular phones with them no matter where they go. A cellular phone provides a ubiquitous means for wide area communication today.

In this document, the terminology “network” or “networks” generally refers to a communication network or networks, which can be wireless or wired, private or public, or a combination of them, and includes the well-known Internet.

In this document, the terminology “cellular phone” can be generally replaced with any portable personal communication device, which operates based on cellular phone network, wireless phone network, satellite communication network, microwave network, the Internet, or any other networks. For easy explanation, we use the terminology “cellular phone” in our examples throughout this document.

### SUMMARY OF THE INVENTION

An overall objective of the present invention is to provide technology to reduce the probability that preventable tragedies will happen.

Some embodiments provide an early warning to a cellular phone user in the event of an adverse environment, abnormal user health condition, undesirable condition, or an accident.

Other embodiments inform predefined third parties which the user entrusts to handle an emergency situation, such that the third parties can locate and arrange for the rescue of the user.

Yet another embodiment provides real-time information to a combination of a cellular phone and a portable peripheral device to form a more intelligent system to perform various tasks.

In one specific embodiment, an embedded toxic gas sensor can trigger the cellular phone to produce a sound to alert the user. Moreover, the cellular phone can automatically make an emergency call to one or more designated parties for this kind of emergency. The designated party also receives information about the position of the cellular phone, so that the designated responder can find the cellular phone user in a timely manner. Similarly, in case of detecting a fire, a cellular phone can alert the user and automatically make an emergency call to “911” so that the fire department can immediately imitate a rescue mission.

In accordance with another specific embodiment, a gas sensor may be integrated with a cellular phone to detect the breath alcohol level of the user, which is then used to control the operation of the cellular phone.

### BRIEF DESCRIPTION OF THE FIGURES

FIG. 1 illustrates how an intelligent cellular phone can prevent the drunken phone user from making mistakes, and can inform his close friends to locate and send him home.

FIG. 2 (comprising FIG. 2A, and FIG. 2B) is a set of flow charts indicating how the cellular phone shown in FIG. 1 performs this intelligent task.

### DETAILED DESCRIPTION OF CERTAIN PREFERRED EMBODIMENTS AND COMBINATIONS OF EMBODIMENTS

The present invention uses a variety of sensors or equivalent devices for different applications. Since different sensors and devices can be used to reach different purposes, there are many possible embodiments and combinations of embodiments. Accordingly, we will describe in detail only some of the preferred embodiments and some preferred combinations of the embodiments of the present invention.

By integrating an array of sensors into a cellular phone, the microprocessor of the cellular phone can make intelligent decisions on behalf of the users, who often are not even aware of the adverse condition that is detected by the array of sensors.

In one embodiment of the present invention, the array of sensors includes gas sensors, which can detect toxic gases.

In another embodiment of the present invention, the array of sensors includes gas sensors, which can detect and measure the breath alcohol level of the cellular phone user.

In an alternative embodiment of the present invention, the array of sensors includes gas sensors, which can detect smoke caused by fire.

In yet another alternative embodiment of the present invention, the cellular phone may communicate through local area wireless technology such as Bluetooth with a peripheral device, which has detected abnormal health condition such as extremely high blood pressure or irregular heart beat.

Once the array of sensors has detected an adverse condition or the cellular phone has received warning signals from peripheral devices, it will take appropriate actions to protect the user of the cellular phone.

In one embodiment of the present invention, the cellular phone will send an alarm signal to warn the user of the adverse condition such as toxic gases.

In another embodiment of the present invention, the cellular phone will determine its position, call some user-predefined third parties and inform the third parties of the situation and the position of the cellular phone.

Since the position determined by the cellular phone may not have sufficient resolution to locate the cellular phone within a few feet of tolerance, in one embodiment of the present invention, the cellular phone will begin transmitting a distinctive location beacon signal, which will help the third parties to easily locate the cellular phone and take the appropriate action such as sending the user to a hospital.

There are many known ways to determine the precise position of the cellular phone. For example, since a cellular phone tower, which receives the signal sent by the cellular phone, can determine the distance from and/or direction of the cellular phone, two or more cellular phone towers can use known triangulation techniques to jointly determine the precise location of the cellular phone and inform the cellular phone of its exact position. Alternatively, each cellular phone tower can send the aforementioned distance and direction information to the cellular phone and the cellular phone can calculate and determine its location by itself. Another possible approach is to include global position circuitry into the cellular phone so that the cellular phone knows its precise position.

When the rescue team gets close to the position of the cellular phone, it can use any precise location information received from the cellular phone or can easily trace any distinctive location beacon signal sent by the cellular phone to precisely locate the cellular phone and rescue the user in time.

When an intoxicated person becomes excited, he/she may be tempted to make phone calls to whoever comes to his/her mind, such as a boss, girlfriend, boyfriend, ex-boyfriend, ex-girlfriend, partner, enemy, etc. Since such an intoxicated person typically has little self-control, such a spontaneous phone call may have a very damaging effect on the relationship. Worst of all, most drunken people do not even remember what has happened and they do not know how to salvage the situation.

In the event that a high breath alcohol level is detected by the array of sensors, in one embedment of the present invention, the cellular phone will automatically block phone conversations with some user-predefined numbers.

In another embodiment of the present invention, the cellular phone may inform the phone company to begin recording all phone conversations because the user may not remember the conversation when he/she becomes sober later.

In an alternative embodiment of the present invention, the cellular phone will automatically call and provide the cellular phone position information to user-predefined third parties, which the user entrusts to send the user home when the user is drunk.

Since the cellular phone can measure the breath alcohol level of the user, it can show the measured result to the user through the cellular phone display so that the user can decide when to stop drinking and when not to drive a car.

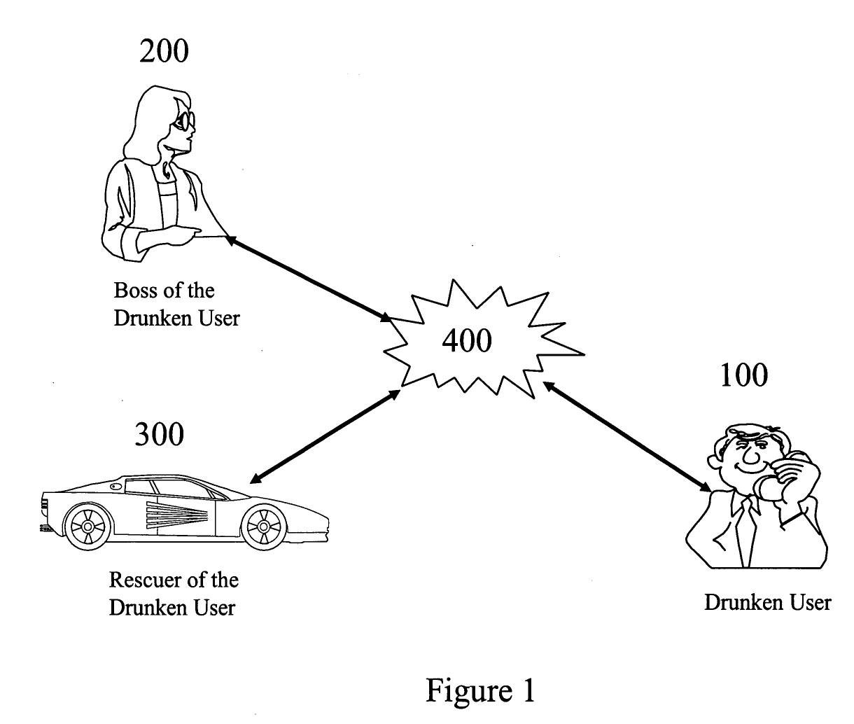

As contemplated in the described embodiments, one of the possible combinations of the preferred embodiments is given below as an example. As shown in FIG. 1, a drunken cellular phone user 100 becomes excited and begins calling whoever comes to his mind through the cellular phone network 400. However, the intelligent cellular phone shall block him from any phone conversation with his boss 200, whom the user 100 definitely does not like to talk to when the user 100 is drunk. In addition, a close friend 300 of the user 100 receives a phone call from the intelligent cellular phone, learns about the situation, and tries to locate and send the user 100 back home.

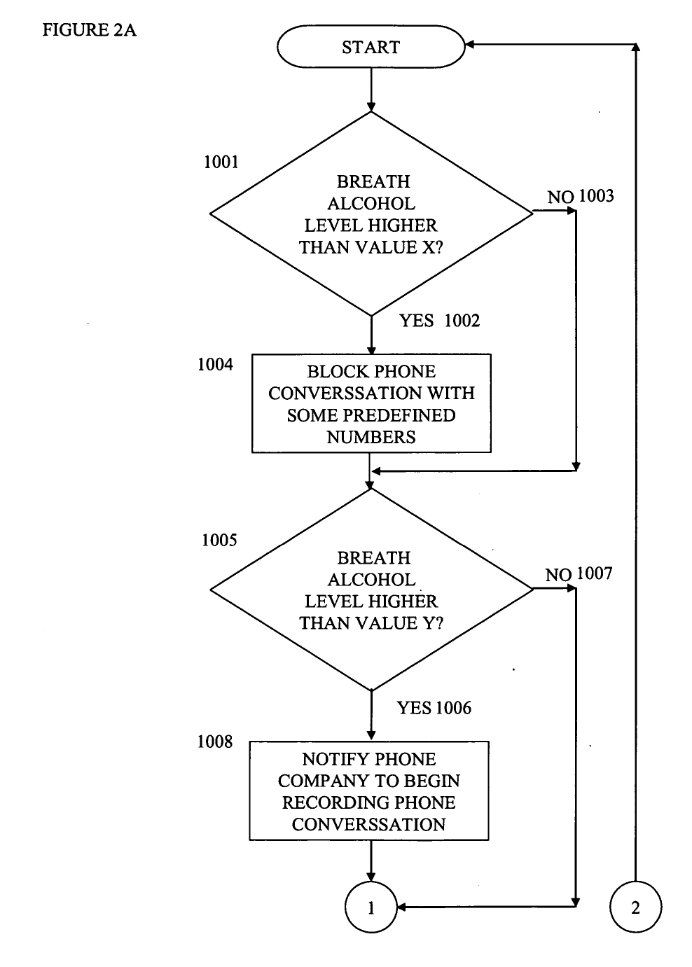

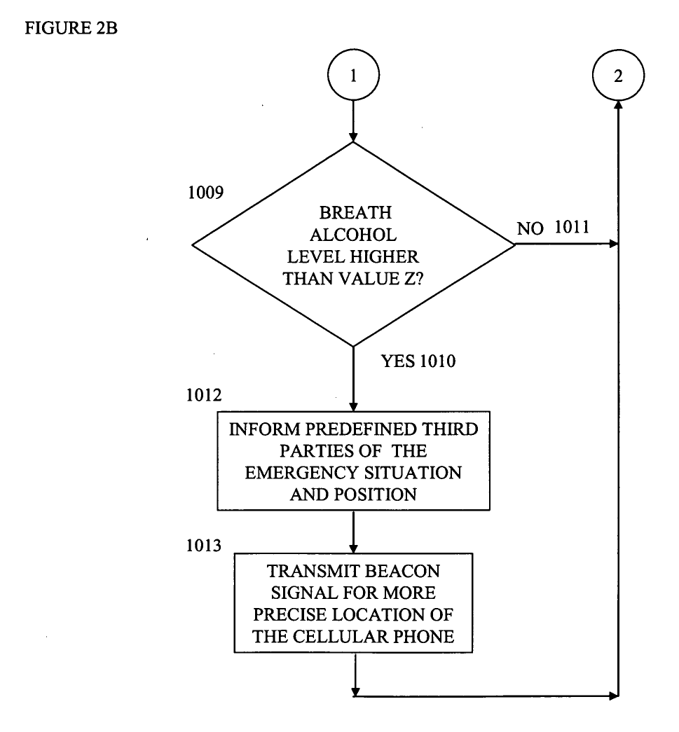

References should now be made to the flowchart of FIG. 2 in combination with the system diagram of FIG. 1, which together illustrate how the intelligent cellular phone will work under such circumstances.

First (decision block 1001), a gas sensor measures the breath alcohol level of the user 100, who is making a phone call, and the microprocessor of the cellular phone compares the measured result with a user-predefined level X.

If the breath alcohol level is same or lower than X (NO block 1003), no action is taken.

However, if the breath alcohol level is higher than X (YES block 1002), the intelligent cellular phone will automatically block all phone conversations with some user-predefined numbers (block 1004), which include the boss 200 of the drunken user 100.

Then (decision block 1005), the gas sensor measures the breath alcohol level of the user 100 and the microprocessor of the cellular phone compares the measured result with a user-predefined level Y.

If the breath alcohol level is same or lower than Y (NO block 1007), no special action is taken.

However, if the breath alcohol level is higher than Y (YES block 1006), the intelligent cellular phone will notify the phone company to begin recording phone conversations (block 1008), which the user 100 may not remember later.

To further protect the user (decision block 1009), the gas sensor also measures the breath alcohol level of the user 100 and the microprocessor of the cellular phone compares the measured result with a user predefined level Z.

If the breath alcohol level is same or lower than Z (NO block 1011), no further action is taken.

However, if the breath alcohol level is higher than Z (YES block 1010), the intelligent cellular phone will automatically call and inform some user-predefined close friend 300, whom the user 100 entrusts to handle such kind of situation on behalf of the user 100, of the situation and the position of the intelligent cellular phone (Block 1012).

In addition (Block 1013), the intelligent cellular phone will transmit a distinctive location beacon signal which can be used by the friend 300 to easily locate the intelligent cellular phone and the user 100, when he/she arrives at the nearby area.

For easy explanation, we have used the sequence X, Y, Z in the above example. However, there is no restriction about the relative magnitude or sequence of the numbers X, Y, and Z. Any of these numbers can be larger or smaller than the others.

This example is given to illustrate how an intelligent cellular phone can protect and rescue a drunken user. By using different sensors, an intelligent cellular phone can serve many other purposes, as will be apparent to those skilled in the art.

In one embodiment of the present invention, with the local area wireless technology such as Bluetooth, a cellular phone can communicate with a portable personal monitor, which can detect abnormal health condition of the user and rescue the user in the event of emergency.

A person often cannot move easily after a serious accident such as a car crash. A user may not be able to reach for his/her cellular phone, which may be thrown far away from the user due to the accident. If such an event occurs in a rural area during the late evening, the chance for the user to get any help is extremely low although timely rescue is extremely important after an accident.

Under such circumstances, a portable personal device, such as a watch, can send a signal to the cellular phone through a local-area wireless technology to make an emergency call and inform predefined parties, which the user entrusts to handle this kind of accidents, of the situation and the position of the cellular phone.

At the same time, the cellular phone will begin transmitting a distinctive location beacon signal, which the third parties can use to locate the user.

In addition to the life-saving situation as described above, other embodiments of the present invention can also provide additional convenience to the users. For example, when a user encounters a traffic jam, an intelligent phone of the present invention might send a signal to a service organization, which will identify the location of the user and help the user to reroute his driving path to avoid the traffic jam.

Alternatively, an intelligent cellular phone might communicate with the navigation system on the car through Bluetooth wireless technology so that the navigation system can integrate the real-time traffic information provided by a cellular-phone based service organization to find the optimal path for the user to avoid any traffic jam.

In yet another embodiment, a patient's body may be monitored by another device to detect a specific emergency condition, such as high blood pressure, etc. When this patient encounters an emergency condition, the monitoring device may automatically transmit a signal to the cellular phone through a local-area wireless technology such as Bluetooth. The cellular phone may then make a phone call to inform a designated third party, for example, a “911” operator, or a paramedic dispatcher, or the emergency room of a hospital, who can immediately initiate a rescue mission based on the position information provided by the intelligent cellular phone, and preferably using a distinctive location beacon signal sent by the cellular phone to locate the person with the emergency condition.

Those skilled in the art will undoubtedly recognize that the described embodiments can be assembled in various ways to form a variety of applications based on the need, and that obvious alterations and changes in the described structure may be practiced without meaningfully departing from the principles, spirit and scope of this invention. Accordingly, such alterations and changes should not be construed as substantial deviations from the present invention as set forth in the appended claims.

1. An intelligent portable personal communication device, comprising:
at least one sensor for detecting a predefined condition; and
means for determining the current position of the device;
wherein the device, in response to the detection of said predefined condition automatically notifies at least one predefined party of said predefined condition and said current position so that the predefined party is enabled to take actions based on the position of the user and the reported condition.

2. The device of claim 1 wherein the intelligent portable personal communication device interfaces another portable peripheral device wirelessly; and
the intelligent portable personal communication device utilizes information received from said portable peripheral device to determine whether said predefined condition has been met.

3. The device of claim 1 wherein:
the at least one sensor includes an array of semiconductor gas sensors.

4. The device of claim 3 wherein:
the semiconductor gas sensors are capable of detecting at least toxic gases.

5. The device of claim 3 wherein:
the semiconductor gas sensors are capable of detecting at least smoke caused by fire.

6. The device of claim 3 wherein:
the semiconductor gas sensors are capable of detecting at least the breath alcohol level of the user.

7. The device of claim 6 further comprising:
means for blocking a communication through the portable personal communication device with certain predefined parties when the breath alcohol of the user reaches a predefined level.

8. The device of claim 6 further comprising:
means for initiating remote recording when a breath alcohol of the user reaches a predefined level.

9. The device of claim 6 further comprising:
means for informing the user of a detected breath alcohol level so that he/she can decide when to stop drinking and when not to drive a vehicle.

10. The device of claim 1 wherein:
the portable personal communication device includes a device selected from the group consisting essentially of cellular phone, wireless phone, satellite phone, microwave phone, internet phone, personal digital assistant, palm computer, email communicator, instant message communicator, and Internet browsing device.

11. The device of claim 1 wherein:
the position information of the portable personal communication device is sent to a networked computer system; and
said networked computer system uses the position information of more than one participating party to coordinate joint activities among said participating parties through their portable personal communication devices.
